(19) United States
(12) Patent Application Publication
(10) Pub. No.: US 2011/0084253 A1
(43) Pub. Date: Apr. 14, 2011

(54) ORGANIC LIGHT EMITTING DIODE LIGHTING APPARATUS AND METHOD FOR MANUFACTURING THE SAME

(75) Inventor: Jin-Kwang Kim, Yongin-City (KR)

(73) Assignee: SAMSUNG MOBILE DISPLAY CO., LTD., Yongin-City (KR)

(21) Appl. No.: 12/859,616

(22) Filed: Aug. 19, 2010

(30) Foreign Application Priority Data
Oct. 12, 2009 (KR) 10-2009-0096859

(51) Int. Cl. H01L 51/52; H01L 51/56

(52) U.S. Cl. 257/40; 438/29; 257/E51.022; 257/E51.021

(57) ABSTRACT

Disclosed herein is an organic light emitting diode lighting apparatus and a method for manufacturing the same. The organic light emitting diode lighting apparatus may include a transparent substrate main body having a plurality of groove lines formed thereon, an auxiliary electrode formed in at least one of the plurality of groove lines, a first electrode formed on the substrate main body so as to contact the auxiliary electrode, an organic emission layer formed on the first electrode and a second electrode formed on the organic emission layer.

### CROSS-REFERENCE TO RELATED APPLICATIONS

This application claims priority to and the benefit of Korean Patent Application No. 10-2009-0096859 filed in the Korean Intellectual Property Office on Oct. 12, 2009, the entire contents of which are incorporated herein by reference.

### BACKGROUND

1. Field of the Invention

The described technology relates generally to a lighting apparatus. More particularly, the described technology relates generally to an organic light emitting diode lighting apparatus with an organic light emitting diode and a method for manufacturing the same.

2. Description of the Related Art

An organic light emitting diode may include a hole injection electrode, an organic emission layer and an electron injection electrode. The organic light emitting diode emits light by energy that is generated when an emission is generated by coupling of electrons and holes and the electron falls from an exited state to a ground state within the organic emission layer.

An organic light emitting diode lighting apparatus uses an organic light emitting diode that becomes a surface light source. Thus, the organic light emitting diode lighting apparatus can be used for various purposes by taking advantage of the surface light source. At least one of the hole injection electrode and the electron injection electrode of the organic light emitting diode lighting apparatus is formed of a transparent conductive material that can transmit light. However, the transparent conductive material has relatively high sheet resistance. Thus, if the transparent conductive material is used as it is as an electrode, an unnecessary voltage drop occurs and luminance becomes non-uniform. Moreover, although the organic light emitting diode lighting apparatus is a surface light source, the organic emission layer that actually produces light will emit light in many directions. As a result, light emitted from the organic emission layer in a direction crossing the hole injection electrode or the electron injection electrode is effectively utilized, while light emitted in other directions is wasted.

### SUMMARY OF CERTAIN INVENTIVE ASPECTS

In one aspect, an organic light emitting diode lighting apparatus that improves optical efficiency.

In another aspect, a method for manufacturing the organic light emitting diode lighting apparatus.

In another aspect an organic light emitting diode lighting apparatus includes, for example, a transparent substrate main body having a plurality of groove lines formed thereon; an auxiliary electrode formed in at least one of the plurality of groove lines; a first electrode formed on the substrate main body so as to contact the auxiliary electrode; an organic emission layer formed on the first electrode; and a second electrode formed on the organic emission layer.

In some embodiments, the auxiliary electrode has a thickness within the range of about 2 μm to about 100 μm. In some embodiments, the plurality of groove lines has a depth of less than about 50% of the thickness of the substrate main body. In some embodiments, the auxiliary electrode has a width within the range of about 1 μm to about 50 μm. In some embodiments, the entire area of the auxiliary electrode is no more than about 15% of an actual emission area of the organic emission layer. In some embodiments, the first electrode comprises a transparent material and the second electrode comprises a reflective material. In some embodiments, the first electrode has a thickness of less than about 200 nm. In some embodiments, the auxiliary electrode comprises a conductive reflective material and the auxiliary electrode comprises a material having lower resistivity than that of the first electrode. In some embodiments, the substrate main body comprises a glass-based material and the substrate main body has a thickness within the range of about 0.2 mm to about 1.2 mm. In some embodiments, the substrate main body comprises a plastic-based material and the substrate main body has a thickness within the range of about 0.01 mm to about 1 mm. In some embodiments, the organic light emitting diode lighting apparatus further includes a separating barrier rib layer formed between the first electrode and the second electrode so as to overlap the auxiliary electrode.

In another aspect, a method for manufacturing an organic light emitting diode lighting apparatus includes, for example, forming a plurality of groove lines on a transparent substrate main body; forming an auxiliary electrode in at least one of the plurality of groove lines formed on the substrate main body; forming a first electrode on the substrate main body so as to contact the auxiliary electrode; forming an organic emission layer on the first electrode; and forming a second electrode on the organic emission layer.

In some embodiments, the auxiliary electrode has a thickness within the range of about 2 μm to about 100 μm. In some embodiments, the plurality of groove lines has a depth of less than about 50% of the thickness of the substrate main body. In some embodiments, the auxiliary electrode has a width within the range of about 1 μm to about 50 μm. In some embodiments, the first electrode comprises a transparent material and the second electrode comprises a reflective material. In some embodiments, the first electrode has a thickness of less than about 200 nm. In some embodiments, the auxiliary electrode comprises a conductive reflective material and the auxiliary electrode comprises a material having lower resistivity than that of the first electrode. In some embodiments, the plurality of groove lines are formed by a short pulse laser or by removing parts of the substrate main body with an etching process. In some embodiments, the substrate main body comprises a glass-based material and the substrate main body has a thickness within the range of about 0.01 mm to about 1 mm. In some embodiments, the substrate main body comprises a plastic-based material and the substrate main body has a thickness within the range of about 0.01 mm to about 1 mm. In some embodiments, the method further includes, for example, forming a separating barrier rib layer disposed between the first electrode and the second electrode so as to overlap the auxiliary electrode.

### BRIEF DESCRIPTION OF THE DRAWINGS

Features of the present disclosure will become more fully apparent from the following description and appended claims, taken in conjunction with the accompanying drawings. It will be understood these drawings depict only certain embodiments in accordance with the disclosure and, therefore, are not to be considered limiting of its scope; the disclosure will be described with additional specificity and detail through use of the accompanying drawings. An apparatus according to some of the described embodiments can have several aspects, no single one of which necessarily is solely responsible for the desirable attributes of the apparatus. After considering this discussion, and particularly after reading the section entitled “Detailed Description of Certain Inventive Embodiments” one will understand how illustrated features serve to explain certain principles of the present disclosure.

FIG. 1 is a layout view of an organic light emitting diode lighting apparatus according to one exemplary embodiment.

FIG. 2 is a cross-sectional view taken along line II-II.

FIGS. 3 to 6 are cross-sectional views sequentially showing a manufacturing process of the organic light emitting diode lighting apparatus of FIG. 1.

FIG. 7 is a graph showing the distribution of luminance according to an experimental example and comparative examples.

### DETAILED DESCRIPTION OF CERTAIN INVENTIVE EMBODIMENTS

In the following detailed description, only certain exemplary embodiments have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive. In addition, when an element is referred to as being “on” another element, it can be directly on the other element or be indirectly on the other element with one or more intervening elements interposed therebetween. Also, when an element is referred to as being “connected to” another element, it can be directly connected to the other element or be indirectly connected to the other element with one or more intervening elements interposed therebetween. Hereinafter, like reference numerals refer to like elements. To clearly describe the exemplary embodiment, parts not related to the description are omitted, and like reference numerals designate like components throughout the specification. In the drawings, the sizes and thicknesses of the components are merely shown for convenience of explanation, and therefore the exemplary embodiment is not limited to the illustrations described and shown herein. In the drawings, the thickness of layers, films, panels, regions, etc., are exaggerated for clarity. In the drawings, the thicknesses of some layers and areas are exaggerated for convenience of explanation.

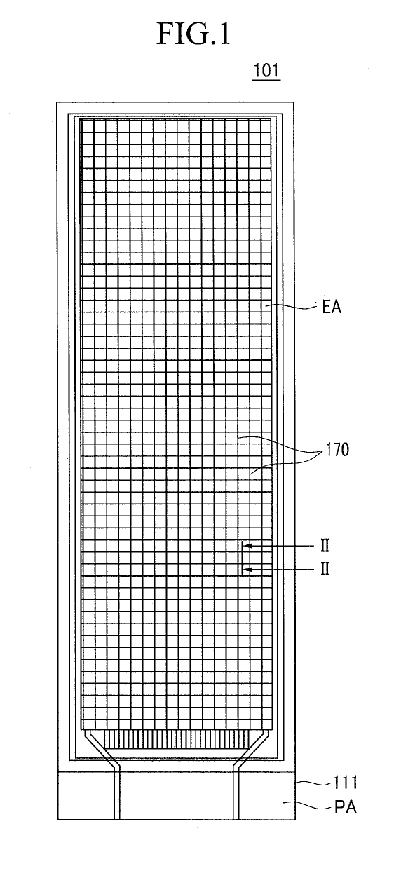

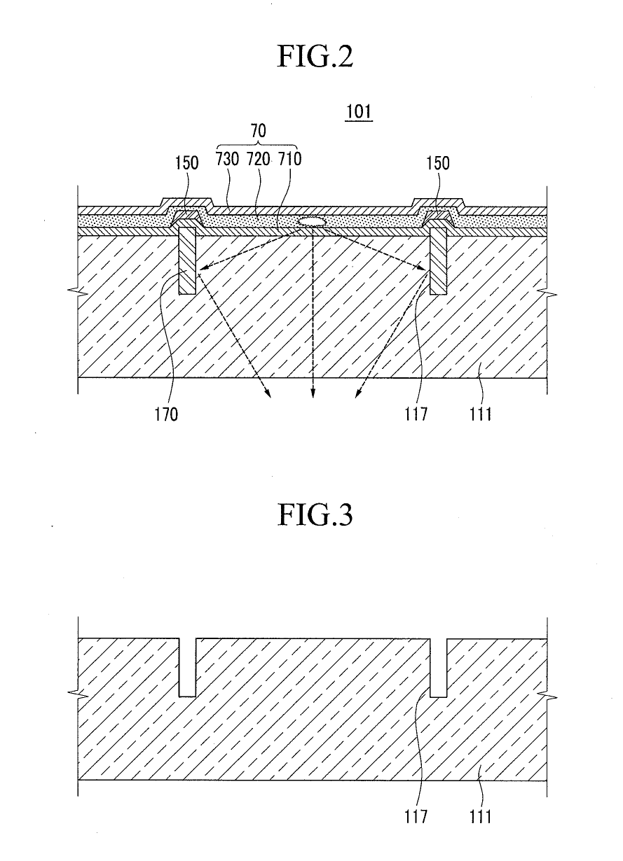

As shown in FIGS. 1 and 2, an organic light emitting diode lighting apparatus 101 includes a substrate main body 111, an auxiliary electrode 170, a first electrode 710, an organic emission layer 720, and a second electrode 730. Here, the first electrode 710, the organic emission layer 720, and the second electrode 730 constitute an organic light emitting diode OLED 70. The organic light emitting diode lighting apparatus 101 may further comprise a separating barrier rib layer 150.

The substrate main body 111 is formed of a transparent insulating material. Concretely, the substrate main body 111 may be an insulating substrate made of glass, quartz, ceramic, plastic, or the like. The substrate main body 111 is divided into an emitting area EA and a pad area PA. The substrate main body 111 has a plurality of groove lines 117 formed thereon. The plurality of groove lines 117 are formed in various geometric patterns, including, for example, a stripe pattern and/or a lattice pattern.

The substrate main body 111 may include a glass-based material. The substrate main body 111 may have a thickness within the range of about 0.2 mm to about 1.2 mm. The thickness of the substrate main body 111 may vary depending on the material, processing method, purpose, etc. If the substrate main body 111 has a thickness of less than about 0.2 mm, this makes it difficult to stably support several thin films to be formed on the substrate main body 111. In contrast, if the substrate main body 111 has a thickness of more than about 1.2 mm, the overall thickness of the organic light emitting diode lighting apparatus 101 would become unnecessarily large, the manufacturing cost would increase and the productivity decrease. However, the exemplary embodiment of the substrate main body 111 is not limited to the above description. For example, the substrate main body 111 may include a plastic-based material. In some embodiments, the substrate main body 111 may include polyimide (PI) having excellent heat resistance. In the case where the substrate main body 111 is made of a plastic-based material, it may have a thickness within the range of about 0.01 mm to about 1 mm. Moreover, it is possible to form a flexible organic light emitting diode lighting apparatus 101.

Furthermore, in the case where it is desired to form the substrate main body 111 at a relatively very small thickness of about 0.1 mm or less, the organic light emitting diode lighting apparatus 101 can be manufactured by forming the substrate main body 111 from a plastic material on a glass substrate (not shown), forming several thin films thereon to complete the organic light emitting diode lighting apparatus 101, and then separating the substrate main body 111 and the glass substrate (not shown).

The thinner the substrate main body 111 is, the more effectively the flexible organic light emitting diode lighting apparatus 101 can be formed. However, if the substrate main body 111 has a thickness of less than about 0.01 mm, this renders it difficult to manufacture the organic light emitting diode lighting apparatus 101 and makes it difficult to support several thin films stably. In contrast, if the substrate main body 111 has a thickness of more than about 1 mm, the overall thickness of the organic light emitting diode lighting apparatus 101 becomes unnecessarily large.

In some embodiments, the plurality of groove lines 117 may have a depth of less than about 50% of the thickness of the substrate main body 111. If the plurality of groove lines 117 has a depth of about 50% or more of the thickness of the substrate main body 111, the strength of the substrate main body 111 may be lowered. That is, the substrate main body 111 may be easily broken or damaged along the groove lines 117.

The auxiliary electrode 170 is formed by filling in one or more of the plurality of groove lines 117. The auxiliary electrode 170 is formed of a conductive reflective material. That is, the auxiliary electrode 170 may include a metal material that has low resistivity and reflects light. For example, the auxiliary electrode 170 may include a material such as lithium (Li), calcium (Ca), lithium-fluoride-calcium (LiF/Ca), lithium-fluoride-aluminum (LiF/AI), aluminum (Al), silver (Ag), magnesium (Mg), or gold (Au). Moreover, because the auxiliary electrode 170 may fill in the plurality of grooves lines 117, the auxiliary electrode 170 may be formed in various geometric patterns, including, for example, a stripe pattern and/or a lattice pattern, such the groove lines 117. The auxiliary electrode 170 may have a thickness within the range of about 2 μm to about 100 μm. Here, the thickness specifically refers to a length formed in a direction crossing the substrate main body 111. Also, the auxiliary electrode 170 has a width within the range of about 1 μm to about 50 μm.

The auxiliary electrode 170 may improve the electrical characteristics of the first electrode 710. The auxiliary electrode 170 may lower sheet resistance. Moreover, the auxiliary electrode 170 may reflect a part of the light emitted from the organic emission layer 720 in various directions to thus improve optical efficiency. That is, the auxiliary electrode 170 may also serve to collect light emitted to the outside from the organic emission layer 720 from the substrate main body 111. The arrows shown by dotted lines in FIG. 2 indicate different paths of light generated from the organic emission layer 720. In this way, the organic light emitting diode lighting apparatus 101 can effectively improve optical efficiency by means of the auxiliary electrode 170.

If the auxiliary electrode 170 has a thickness of less than about 2 μm, the electrical characteristics of the first electrode 710 cannot be effectively improved. Moreover, in order for the auxiliary electrode 170 to have a thickness of more than about 100 μm, the depth of the groove lines 117 filled in with the auxiliary electrode 170 may be large. Therefore, the entire thickness of the substrate main body 111 may be unnecessarily large.

If the auxiliary electrode 170 has a width of less than about 1 μm, the auxiliary electrode 170 may be difficult to stably form. If the auxiliary electrode 170 has a width of more than about 50 μm, the area of an effective light emitting region that actually emits light may be reduced and the luminance of the organic light emitting diode lighting apparatus 101 may become non-uniform.

Moreover, the auxiliary electrode 170 may have a structure where a portion thereof is protruded above the surface of the substrate main body 111. The protruded portion of the auxiliary electrode 170 may allow for stable contact with the first electrode 710, and serve to partition off the emitting area EA of the organic light emitting diode lighting apparatus 101 into a number of cells, along with a separating barrier rib layer 150 to be described later. However, the exemplary embodiment of the auxiliary electrode 170 is not limited to the above description. Thus, the auxiliary electrode 170 may be formed flat against the surface of the substrate main body 111 without any portion protruded above the surface of the substrate main body 111.

The first electrode 710 may be formed on the substrate main body 111 so as to contact the auxiliary electrode 170. In some embodiments, the first electrode 710 includes a transparent conductive material. Examples of the transparent conductive material in the first electrode 710 may include, for example, indium tin oxide (ITO), indium zinc oxide (IZO), zinc oxide (ZnO) or indium oxide (In₂O₃).

The first electrode 710 formed of such a transparent conductive material may have a relatively higher resistivity than that of the auxiliary electrode 170. That is, the larger the area of the first electrode 710 is, the harder it is for the electrical current flowing through the first electrode 710 to be uniform over the entire area of the first electrode 710. If the organic light emitting diode lighting apparatus 101 is provided with the first electrode 710 without an auxiliary electrode, the sheet resistance becomes higher and thus a voltage drop occurs. Therefore, as for light emitted by the organic emission layer 720 formed between the first electrode 710 and the second electrode 730, the larger the area of the first electrode 710 is, the more non-uniform the overall luminance. However, in one exemplary embodiment, the auxiliary electrode 170 assists in making the electrical current flowing through the first electrode 710 uniform over the entire area. That is, the auxiliary electrode 170 makes up for the relatively low electrical conductivity of the first electrode 710, thereby preventing the luminance of the light emitted by the organic emission layer 720 of the organic light emitting diode lighting apparatus 101 from becoming non-uniform over the entire area.

Moreover, the first electrode 710 has a thickness of less than about 200 nm. The thinner the first electrode 710 is, the larger the sheet resistance becomes. However, since the auxiliary electrode 170 makes up for a relatively large amount sheet resistance of the first electrode 710, the thickness of the first electrode 710 can be made much smaller. The thinner the first electrode 710 is, the higher the transmittance of light, and thus the optical efficiency can be further improved.

The separating barrier rib layer 150 may be formed between the first electrode 710 and the second electrode 730 at a position that overlaps with the auxiliary electrode 170. The separating barrier rib layer 150 partitions off the emitting area EA, at which the organic light emitting diode formed of the first electrode 710, the organic emission layer 720, and the second electrode 730 actually emits light, into a number of cells. In the case where a defect such as a short circuit occurs to one region of the organic light emitting diode lighting apparatus 101, the separating barrier rib layer 150 prevents such a defect from spreading over the entire area. Moreover, the separating barrier rib layer 150 may include various insulating films that are well known to those skilled in the art, such as silicon nitride (SiNₓ) and silicon oxide (SiO₂).

The organic emission layer 720 may be formed on the first electrode 710 and the separating barrier rib layer 150. Moreover, the organic emission layer 720 may include a low molecular organic material or a high molecular organic material. The organic emission layer 720 may be formed of a multiple layer including, for example, one or more of an emission layer, a hole injection layer (HIL), a hole transport layer (HTL), an electron transport layer (ETL), and an electron injection layer (EIL). In the case where the organic emission layer 720 includes all of these layers, the hole injection layer is disposed on the first electrode 710 serving as a positive electrode, and then the hole transport layer, the emission layer, the electron transport layer, and the electron injection layer are sequentially stacked on the hole injection layer.

Furthermore, the organic emission layer 720 formed on the separating barrier rib layer 150 may not actually emit light.

Exemplary embodiments of the organic emission layer 720, however, are not limited to the above descriptions. For example, the organic emission layer 720 may not be formed on the separating barrier rib layer 150.

Additionally, the entire area of the auxiliary electrode 170 may be no more than about 15% of the actual emission area of the organic emission layer 720. Because the auxiliary electrode 170 may be unable to transmit light, if the area of the auxiliary electrode 170 becomes too large, the effective emitting area at which the organic emission layer 720 actually emits light becomes smaller, thereby decreasing optical efficiency. In contrast, because the auxiliary electrode 170 reflects light, the auxiliary electrode 170 can reflect a part of the light emitted from the organic emission layer 720 in various directions to thus collect light.

The second electrode 730 may be formed on the organic emission layer 720. The second electrode 730 may also be an electron injection electrode. Moreover, the second electrode 730 may include a reflective material.

Furthermore, in some embodiments the organic emission layer 720 is formed in the emitting area EA of the substrate main body 111, and at least one of the first electrode 710, the auxiliary electrode 170, and the second electrode 730 extends from the emitting area EA of the substrate main body 111 to the pad area PA thereof. The electrodes 170, 710, and 730 extending to the pad area PA of the substrate main body 111 are connected to an external power source in the pad area PA. In addition, though not shown in FIG. 2, the organic light emitting diode lighting apparatus 101 may further include an encapsulating member disposed on the second electrode 730 to protect the organic emission layer 720. At this time, a space between the encapsulating member and the substrate main body 111 is sealed.

The encapsulating member may be formed as an insulation substrate including glass, quartz, ceramic, plastic, or the like, or as a metal substrate made of stainless steel or the like. Moreover, the encapsulating member may be formed of at least one organic or inorganic film, or may be formed of an encapsulating thin film including at least one inorganic film and at least one organic film stacked together.

In some configurations of the embodiments described above, the organic light emitting diode lighting apparatus 101 can effectively improve optical efficiency.

Now, a method for manufacturing an organic light emitting diode lighting apparatus 101 according to one exemplary embodiment will be described with reference to FIGS. 3 to 6. First, as shown in FIG. 3, a plurality of groove lines 117 are formed by using a short pulse laser or by removing parts of a substrate main body 111 by an etching process. Here, the substrate main body 111 is formed of a glass-based material or a plastic-based material. Moreover, the plurality of groove lines 117 has a depth of less than about 50% of the thickness of the substrate main body 111.

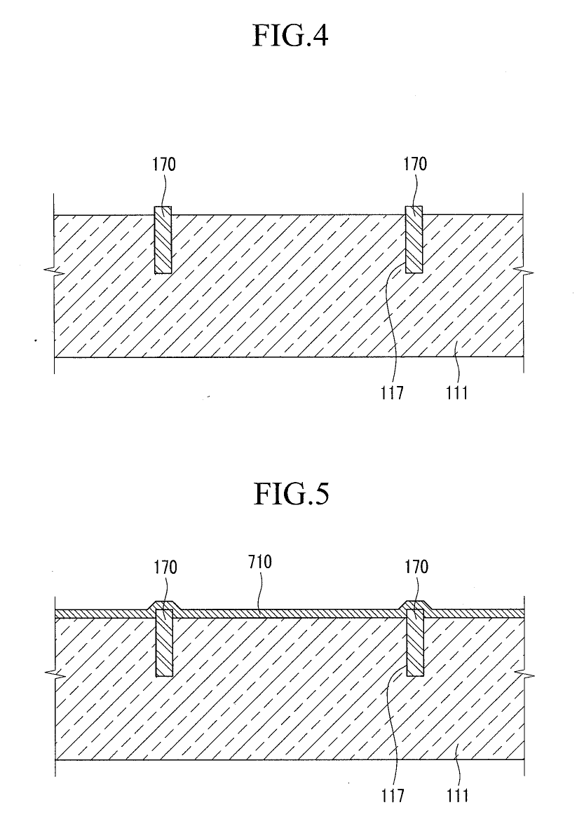

Next, as shown in FIG. 4, the plurality of groove lines 117 of the substrate main body 111 are filled with a conductive reflective material to thus form an auxiliary electrode 170. Here, the conductive reflective material is a metal material that has relatively low resistivity and reflects light. A portion of the auxiliary electrode 170 is protruded above the surface of the substrate main body 111.

Next, as shown in FIG. 5, a first electrode 710 is formed on the substrate main body 111 so as to contact the auxiliary electrode 170. The first electrode 710 is formed of a transparent conductive material, and has relatively higher resistivity than that of the auxiliary electrode 170. Moreover, the first electrode 710 has a thickness of less than about 200 nm.

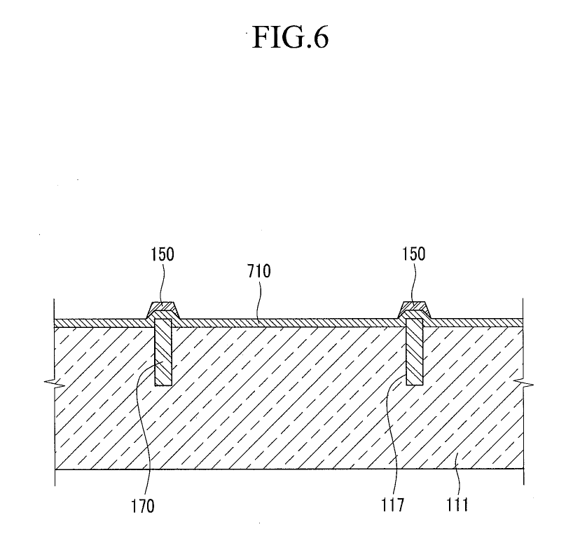

Next, as shown in FIG. 6, a separating barrier rib layer 150 is formed on the first electrode 710 at a position overlapped with the auxiliary electrode 170. The separating barrier rib layer 150, along with the projected portion of the first electrode 710, partitions off an emitting area EA into a number of cells. Further, the separating barrier rib layer 150 is formed of an insulating film such as silicon nitride (SiNₓ) or silicon oxide (SiO₂).

Next, an organic emission layer 720 and a second electrode 730 are sequentially formed to manufacture the organic light emitting diode lighting apparatus 101 according to one exemplary embodiment as set forth in FIG. 2.

By this manufacturing method, the some embodiments of the organic light emitting diode lighting apparatus 101 can be effectively manufactured with improved optical efficiency.

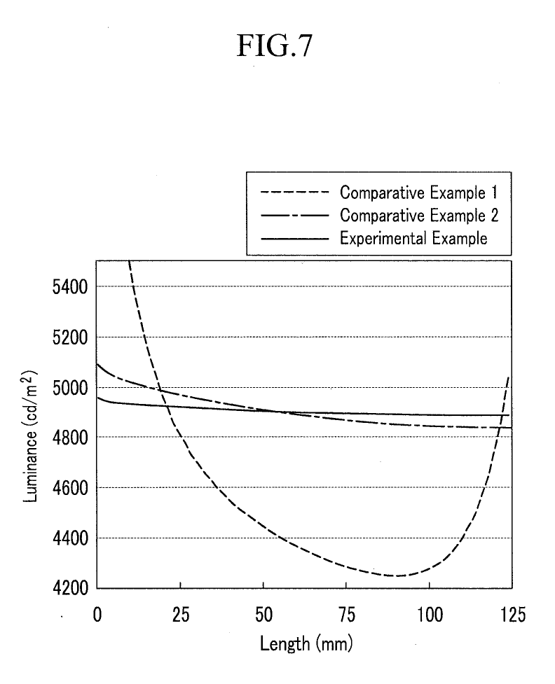

Now, referring to FIG. 7, an experimental example according to the present invention and comparative examples will be discussed. FIG. 7 is a graph showing the distribution of luminance according to an experimental example and comparative examples.

An organic light emitting diode lighting apparatus 101 according to Experimental Example 1 includes an auxiliary electrode 170 made of aluminum (Al) and having a thickness of about 5 μm, at least a portion of which is buried in a substrate main body 111, and a first electrode 710 formed of ITO and having a thickness of about 100 nm.

On the other hand, an organic light emitting diode lighting apparatus 101 according to Comparative Example 1 has no auxiliary electrode, and includes a first electrode formed of ITO and having a thickness of about 200 nm. Also, an organic light emitting diode lighting apparatus 101 according to Comparative Example 2 includes an auxiliary electrode 170 made of aluminum (Al) and having a thickness of about 1 μm, which is formed right above a substrate main body, that is, not buried in the substrate main body, and a first electrode formed of ITO and having a thickness of about 200 nm.

As shown in FIG. 7, from Experimental Example 1, it can be seen that, although the first electrode 710 has a relatively small thickness, it exhibits the most uniform distribution of luminance.

Moreover, in Experimental Example 1, the sheet resistance value, which is the overall sheet resistance of the auxiliary electrode 170 and the first electrode 710, was 0.0095 ohm/sq. On the contrary, Comparative Example 1 and Comparative Example 2 showed sheet resistance values of 10 ohm/sq and 0.0474 ohm/sq, respectively. As described above, it can be seen that Experimental Example 1 according to one exemplary embodiment has a much lower sheet resistance value than those of Comparative Example 1 and Comparative Example 2.

It will be appreciated by those skilled in the art that various modifications and changes may be made without departing from the scope of the present disclosure. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the Figures may be combined, interchanged or excluded from other embodiments. With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. Further, while the present disclosure has described certain exemplary embodiments, it is to be understood that the scope of the disclosure is not limited to the disclosed embodiments, but, on the contrary, is intended to cover various modifications and equivalent arrangements included within the spirit and scope of the appended claims and equivalents thereof.

What is claimed is:

1. An organic light emitting diode lighting apparatus, comprising:
a transparent substrate main body having a plurality of groove lines formed thereon;
an auxiliary electrode formed in at least one of the plurality of groove lines;
a first electrode formed on the substrate main body so as to contact the auxiliary electrode;
an organic emission layer formed on the first electrode; and
a second electrode formed on the organic emission layer.

2. The organic light emitting diode lighting apparatus of claim 1, wherein the auxiliary electrode has a thickness within the range of about 2 μm to about 100 μm.

3. The organic light emitting diode lighting apparatus of claim 2, wherein the plurality of groove lines has a depth of less than about 50% of the thickness of the substrate main body.

4. The organic light emitting diode lighting apparatus of claim 2, wherein the auxiliary electrode has a width within the range of about 1 μm to about 50 μm.

5. The organic light emitting diode lighting apparatus of claim 4, wherein the entire area of the auxiliary electrode is no more than about 15% of an actual emission area of the organic emission layer.

6. The organic light emitting diode lighting apparatus of claim 4, wherein the first electrode comprises a transparent material and the second electrode comprises a reflective material.

7. The organic light emitting diode lighting apparatus of claim 6, wherein the first electrode has a thickness of less than about 200 nm.

8. The organic light emitting diode lighting apparatus of claim 1, wherein the auxiliary electrode comprises a conductive reflective material and the auxiliary electrode comprises a material having lower resistivity than that of the first electrode.

9. The organic light emitting diode lighting apparatus of claim 1, wherein the substrate main body comprises a glass-based material and the substrate main body has a thickness within the range of about 0.2 mm to about 1.2 mm.

10. The organic light emitting diode lighting apparatus of claim 1, wherein the substrate main body comprises a plastic-based material and the substrate main body has a thickness within the range of about 0.01 mm to about 1 mm.

11. The organic light emitting diode lighting apparatus of claim 1 further comprising a separating barrier rib layer formed between the first electrode and the second electrode so as to overlap the auxiliary electrode.

12. A method for manufacturing an organic light emitting diode lighting apparatus, the method comprising:
forming a plurality of groove lines on a transparent substrate main body;
forming an auxiliary electrode in at least one of the plurality of groove lines formed on the substrate main body;
forming a first electrode on the substrate main body so as to contact the auxiliary electrode;
forming an organic emission layer on the first electrode; and
forming a second electrode on the organic emission layer.

13. The method of claim 12, wherein the auxiliary electrode has a thickness within the range of about 2 μm to about 100 μM.

14. The method of claim 13, wherein the plurality of groove lines has a depth of less than about 50% of the thickness of the substrate main body.

15. The method of claim 13, wherein the auxiliary electrode has a width within the range of about 1 μm to about 50 μm.

16. The method of claim 15, wherein the first electrode comprises a transparent material and the second electrode comprises a reflective material.

17. The method of claim 16, wherein the first electrode has a thickness of less than about 200 nm.

18. The method of claim 12, wherein the auxiliary electrode comprises a conductive reflective material and the auxiliary electrode comprises a material having lower resistivity than that of the first electrode.

19. The method of claim 12, wherein the plurality of groove lines are formed by a short pulse laser or by removing parts of the substrate main body with an etching process.

20. The method of claim 12, wherein the substrate main body comprises a glass-based material and the substrate main body has a thickness within the range of about 0.01 mm to about 1 mm.

21. The method of claim 12, wherein the substrate main body comprises a plastic-based material and the substrate main body has a thickness within the range of about 0.01 mm to about 1 mm.

22. The method of claim 12 further comprising forming a separating barrier rib layer disposed between the first electrode and the second electrode so as to overlap the auxiliary electrode.
